(19) United States
(12) Patent Application Publication
(10) Pub. No.: US 2001/0038972 A1
(43) Pub. Date: Nov. 8, 2001

(54) ULTRA-THIN RESIST SHALLOW TRENCH PROCESS USING METAL HARD MASK

(75) Inventors: CHRISTOPHER F. LYONS, FREMONT, CA (US); SCOTT A. BELL, SAN JOSE, CA (US); HARRY J. LEVINSON, SARATOGA, CA (US); KHANH B. NGUYEN, SAN MATEO, CA (US); FEI WANG, SAN JOSE, CA (US); CHIH YUH YANG, SAN JOSE, CA (US)

Correspondence Address: AMIN & TUROCY, LLP, 1900 EAST 9TH STREET, NATIONAL CITY CENTER, 24TH FLOOR,, CLEVELAND, OH, 44114, US

(73) Assignee: Christopher F. Lyons

(21) Appl. No.: 09/197,383

(22) Filed: Nov. 20, 1998

(51) Int. Cl. G03C 5/00; G03F 7/00; H01L 21/76

(52) U.S. Cl. 430/313; 430/311; 430/316; 430/423; 430/424; 430/432

(57) ABSTRACT

A method of forming a shallow trench isolation is provided. In the method, a barrier oxide layer is formed on a substrate, and a silicon nitride layer is formed on the barrier oxide layer. A metal layer is formed on the silicon nitride layer, and an ultra-thin photoresist is formed on the metal layer. The ultra-thin photoresist layer is patterned with short wavelength radiation to define a pattern for a shallow trench. The ultra-thin photoresist layer is used as a mask during a first etch step to transfer the shallow trench pattern to the metal layer. The first etch step includes an etch chemistry that is selective to the metal layer over the ultra-thin photoresist layer. The metal layer is used as a hard mask during a second etch step to form the shallow trench by etching portions of the silicon nitride layer, barrier oxide layer and substrate.

### TECHNICAL FIELD

The present invention generally relates to photo-lithography, and more particularly relates to a method of forming sub-micron shallow trench isolation via short wavelength radiation and ultra-thin photoresists.

### BACKGROUND OF THE INVENTION

In the semiconductor industry, there is a continuing trend toward higher device densities. To achieve these high densities there has been and continues to be efforts toward scaling down the device dimensions on semiconductor wafers. In order to accomplish such high device packing density, smaller and smaller features sizes are required. This may include the width and spacing of shallow trench isolation, interconnecting lines and the surface geometry such as comers and edges of various features.

The requirement of small features with close spacing between adjacent features requires high resolution photolithographic processes. In general, lithography refers to processes for pattern transfer between various media. It is a technique used for integrated circuit fabrication in which a silicon slice, the wafer, is coated uniformly with a radiation-sensitive film, the resist, and an exposing source (such as optical light, x-rays, or an electron beam) illuminates selected areas of the surface through an intervening master template, the photomask, for a particular pattern. The lithographic coating is generally a radiation-sensitized coating suitable for receiving a projected image of the subject pattern. Once the image is projected, it is indelibly formed in the coating. The projected image may be either a negative or a positive of the subject pattern. Exposure of the coating through the photomask causes the image area to become either more or less soluble (depending on the coating) in a particular solvent developer. The more soluble areas are removed in the developing process to leave the pattern image in the coating as less soluble polymer.

Projection lithography is a powerful and essential tool for microelectronics processing. As feature sizes are driven smaller and smaller, optical systems are approaching their limits caused by the wavelengths of the optical radiation. A recognized way of reducing the feature size of circuit elements is to lithographically image the features with radiation of a shorter wavelength. “Long” or “soft” x-rays (a.k.a, extreme ultraviolet (EUV), wavelength range of lambda=50 to 700 Angstroms (Å) are now at the forefront of research in an effort to achieve the smaller desired feature sizes.

Although EUV lithography provides substantial advantages with respect to achieving high resolution patterning, the shorter wavelength radiation is highly absorbed by the photoresist material. Consequently, the penetration depth of the radiation into the photoresist is limited. The limited penetration depth of the shorter wavelength radiation requires the use of ultra-thin photoresists so that the radiation can penetrate the entire depth of the photoresist in order to effect patterning thereof. However, the thinness of such ultra-thin photoresists results in the etch resistance thereof to be relatively low. In other words, the etch protection afforded by ultra-thin photoresists is limited which in turn limits the EUV lithographic process.

### SUMMARY OF THE INVENTION

The present invention relates to a method to facilitate lithographic processes employing extreme ultra-violet (EUV) radiation and/or deep UV radiation in fabricating shallow trenches. As noted above, EUV and deep UV radiation are preferred radiation sources in lithographic processes where fine resolution is desired. The short wavelengths of these types of radiation afford for fine patterning (e.g., <0.25 μm). However, these types of radiation are highly absorbed by photoresist material which consequently limits the depth of penetration by the radiation into the photoresist material.

By employing a hard mask metal layer over a substarte layer to be patterned in connection with the shallow trenches, and under the photoresist material the present invention affords for expanding available etch chemistries useable in EUV and/or deep UV lithographic processes. In particular, these types of lithographic processes require the use of very thin photoresists as a result of the depth of penetration limitations of the short wavelength radiation. Such very thin photoresists are limited in their capacity as etch barriers due to the thickness thereof.

In the present invention, the ultra-thin photoresist is employed in patterning and etching (e.g., via a high selectivity fluorocarbon plasma) the metal layer thereunder to form a hard mask. The hard mask is then employed as a mask for a subsequent silicon nitride etch to form the shallow trenches. Thus, the present invention affords for taking advantage of the fine resolution patterning available from EUV and deep UV lithographic processes and mitigates the limitations associated therewith with respect to etch chemistry.

In accordance with one aspect of the present invention, a method of forming a shallow trench isolation is provided. In the method, a barrier oxide layer is formed on a substrate, and a silicon nitride layer is formed on the barrier oxide layer. A metal layer is formed on the silicon nitride layer, and an ultra-thin photoresist is formed on the metal layer. The ultra-thin photoresist layer is patterned with short wavelength radiation to define a pattern for a shallow trench. The ultra-thin photoresist layer is used as a mask during a first etch step to transfer the shallow trench pattern to the metal layer. The first etch step includes an etch chemistry that is selective to the metal layer over the ultra-thin photoresist layer. The metal layer is used as a hard mask during a second etch step to form the shallow trench by etching portions of the silicon nitride layer, barrier oxide layer and substrate.

Another aspect of the present invention provides for a shallow trench isolation (STI) structure having a width below about 0.18 μm. The STI structure is formed by the aforementioned method.

Still another aspect of the present invention relates to a method of forming a shallow trench isolation. In the method a barrier oxide layer is formed on a substrate, the barrier oxide having a thickness within the range of about 50 Å to 150 Å. A silicon nitride layer is formed on the barrier oxide layer, the silicon nitride layer having a thickness within the range of about 1000 Å to 2000 Å. A metal layer is formed on the silicon nitride layer, the metal layer having a thickness within the range of about 100 Å to 1000 Å. An ultra-thin photoresist layer is formed on the metal layer, the ultra-thin photoresist layer having a thickness within the range of about 500 Å to 5000 Å. The ultra-thin photoresist layer is patterned with short wavelength radiation to define a pattern for a shallow trench. The patterned ultra-thin photoresist layer is used as a mask during a first etch step to transfer the shallow trench pattern to the metal layer, the first etch step including an etch chemistry that is selective to the metal layer over the ultra-thin photoresist layer. The patterned metal layer is used as a hard mask during a second etch step to form the shallow trench by etching portions of the silicon nitride layer, barrier oxide layer and substrate.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a prior art schematic cross-sectional illustration of a conventional patterned resist used in shallow trench formation;

FIG. 2 is a perspective illustration of a shallow trench formed in accordance with one aspect of the present invention;

FIG. 3 is a schematic cross-sectional illustration of a silicon substrate having a barrier oxide layer formed thereon in accordance with one aspect of the present invention;

FIG. 4 is a schematic cross-sectional illustration of a silicon nitride layer formed over the barrier oxide layer of FIG. 3 in accordance with one aspect of the present invention;

FIG. 5 is a schematic cross-sectional illustration of a metal layer formed over the silicon nitride layer of FIG. 4 in accordance with one aspect of the present invention;

FIG. 6 is a schematic cross-sectional illustration of an ultra-thin photoresist layer formed over the metal layer of FIG. 5 in accordance with one aspect of the present invention;

FIG. 7 is a schematic cross-sectional illustration of the ultra-thin photoresist layer of FIG. 6 undergoing a patterning step in accordance with one aspect of the present invention;

FIG. 8 is a schematic cross-sectional illustration of the ultra-thin photoresist layer of FIG. 7 after the patterning step is substantially complete in accordance with one aspect of the present invention;

FIG. 9 is a schematic cross-sectional illustration of the metal layer of FIG. 8 undergoing an etching step in accordance with one aspect of the present invention;

FIG. 10 is a schematic cross-sectional illustration of the metal layer of FIG. 9 after the etching step is substantially complete in accordance with one aspect of the present invention;

FIG. 11 is a schematic cross-sectional illustration of the silicon nitride layer, barrier oxide layer and substrate of FIG. 10 undergoing an etching step in accordance with one aspect of the present invention;

FIG. 12 is a schematic cross-sectional illustration of the silicon nitride layer, barrier oxide layer and substrate of FIG. 11 after the etching step is substantially complete to form a shallow trench in accordance with one aspect of the present invention;

FIG. 13 is a schematic cross-sectional illustration of the trench structure of FIG. 12 undergoing a photoresist stripping and hardmask removal step in accordance with one aspect of the present invention;

FIG. 14 is a schematic cross-sectional illustration of the trench structure of FIG. 13 after the photoresist stripping and hardmask removal step is substantially complete in accordance with one aspect of the present invention;

FIG. 15 is a schematic cross-sectional illustration of the trench of FIG. 14 undergoing a filling step with an insulating dielectric material in accordance with one aspect of the present invention;

FIG. 16 is a schematic cross-sectional illustration of the trench of FIG. 15 after the filling step is substantially complete in accordance with one aspect of the present invention;

FIG. 17 is a schematic cross-sectional illustration of the filler of FIG. 16 undergoing a planarization process in accordance with one aspect of the present invention;

FIG. 18 is a schematic cross-sectional illustration of the shallow trench substantially complete in accordance with one aspect of the present invention; and

FIG. 19 is a perspective illustration of the shallow trench of FIG. 18 in accordance with one aspect of the present invention;

### DETAILED DESCRIPTION OF THE INVENTION

The present invention will now be described with reference to the drawings, wherein like reference numerals are used to refer to like elements throughout. The method of the present invention will be described with reference to the formation of a shallow trench via a photolithographic process employing radiation of short wavelength (e.g., EUV radiation and/or deep UV radiation) and an ultra-thin photoresist. The following detailed description is of the best modes presently contemplated by the inventors for practicing the invention. It should be understood that the description of these preferred embodiments are merely illustrative and that they should not be taken in a limiting sense.

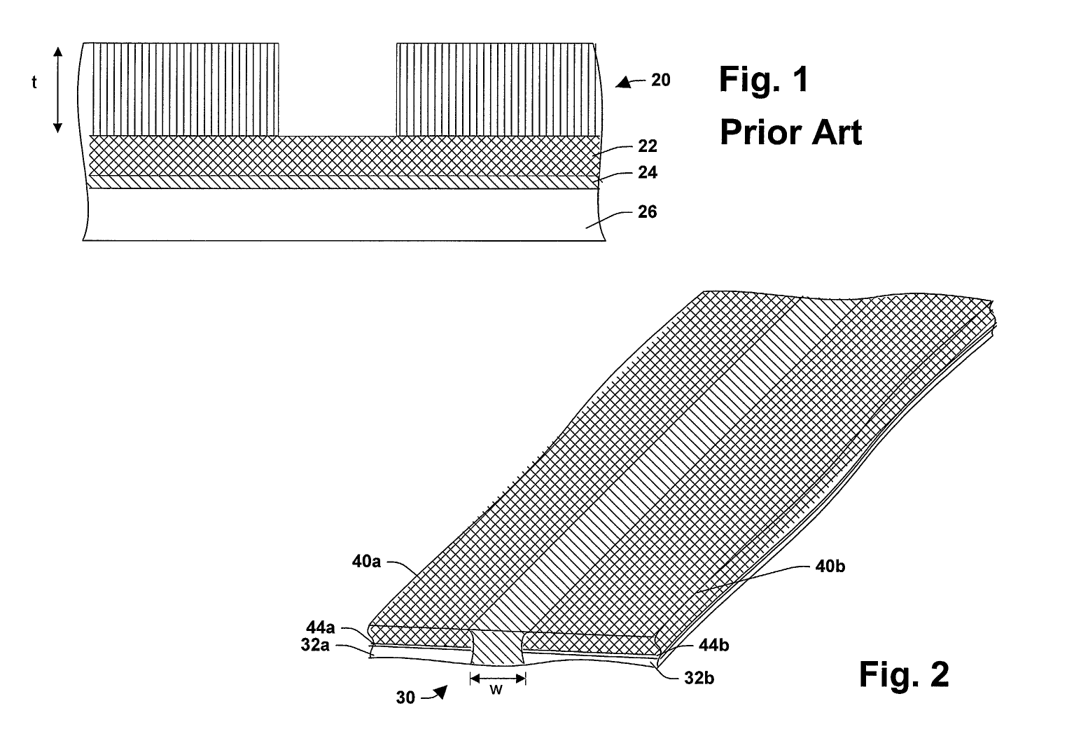

FIG. 1 is a cross-sectional illustration of a conventional photoresist layer 20 being used in the formation of a shallow trench. As can be seen, the photoresist layer 20 is substantially thick (e.g., 5,000-10,000 Å). The photoresist layer 20 is shown patterned so as to define a shallow trench which will be etched into the underlying silicon nitride layer 22, barrier oxide layer 24 and substrate 26. However, the thickness of the photoresist 22 is not conducive for use with short wavelength radiation because these types of radiation would be highly absorbed by the photoresist layer 20 and not penetrate the entire thickness “t” of the layer 20. As a result, such a conventional scheme for forming a shallow trench would not be able to take advantage of the improved resolution of patterning offered by the short wavelength radiation.

Turning now to the present invention in detail, FIG. 2 illustrates a shallow trench 30 formed in accordance with the present invention. In recent years, shallow trench isolation (STI) has become increasingly popular as a means for electrically isolating devices from one another in integrated circuits. Instead of forming insulating regions around devices through local oxidation of silicon (LOCOS), trenches are etched into the substrate and then filled with insulating material (e.g., SiO, SiO₂). Trench isolation has become a preferred form of isolation at sub-micron levels because it avoids the problems of unacceptably large encroachment of field oxides into device active regions and surface topography associated with the bird's beak structure of LOCOS.

The shallow trench 30 provides for separating substrate regions 32a, 32b, Si₃N₄ regions 40a, 40b and barrier oxide regions 44a, 44b which may be respectively associated with different devices of an integrated circuit, for example. The barrier oxide regions 44a, 44b are interposed between the substrate 32 and the Si₃N₄ regions 40a, 40b, respectively. The barrier oxide regions 44 facilitate arresting of interdiffusion of contaminants into the substrate 32.

The shallow trench 30 is formed via photolithographic techniques utilizing short wavelength radiation and ultra-thin photoresists. Accordingly, substantially smaller dimensions of the shallow trench 30 are achieved as compared to a shallow trench formed in accordance with the prior art technique discussed with respect to FIG. 1. For example, the shallow trench 30 may have a width “w” less than about 0.25 μm, and such small dimension is not obtainable using conventional lithographic processes. In another embodiment, the shallow trench 30 may have a width “w” less than about 0.18 μm.

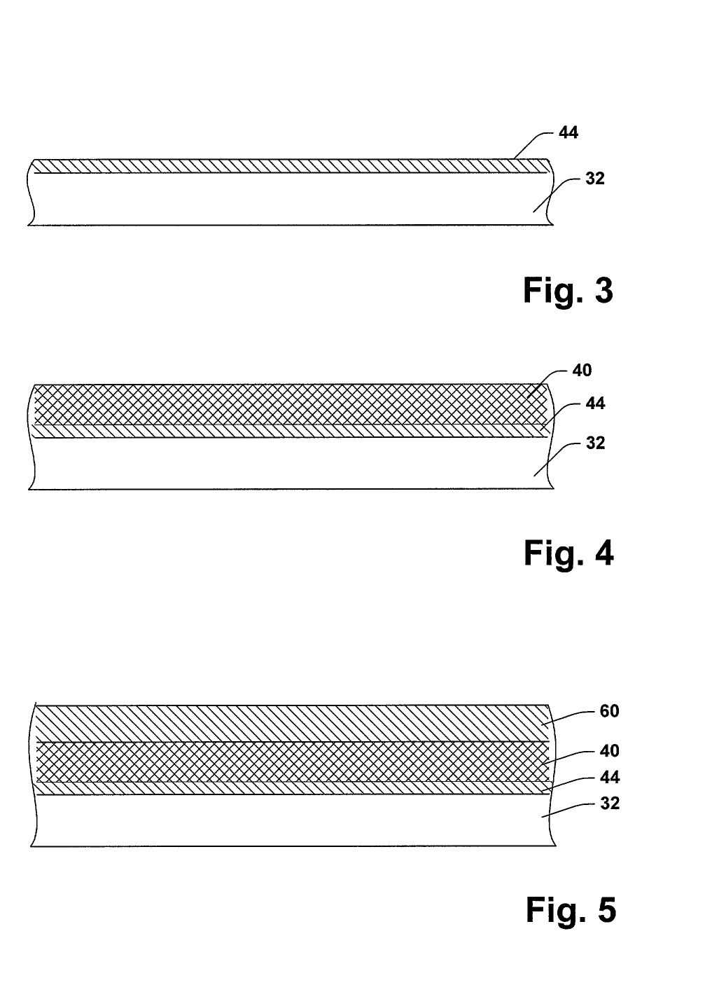

Turning now to FIGS. 3-16, the fabrication of the shallow trench 30 is discussed in greater detail. FIG. 3 is a cross-sectional illustration of the substrate 32 and barrier oxide layer 44 formed thereon. The substrate 32 may be p-type or n-type silicon, for example.

The barrier oxide 44 is preferably within the range of 50 Å-150 Å, however, any thickness suitable for carrying out the aforementioned function of the barrier oxide may be employed. Likewise, any suitable material (e.g., SiO, SiO₂) may be employed as the barrier layer 44.

FIG. 4 illustrates the Si₃N₄ layer 40 formed over the barrier layer 44. The Si₃N₄ layer 40 will serve as a stop layer for a subsequent chemical mechanical polishing (CMP) step (FIG. 17). The Si₃N₄ layer 40 may be deposited by any suitable process (e.g., Low Pressure Chemical Vapor Deposition (LPCVD), Plasma Enhanced Chemical Vapor Deposition (PECVD), or High Density Chemical Vapor Deposition (HDCVD)) to a thickness between about 1,000 Å-2,000 Å. The temperature ranges to form the Si₃N₄ layer 44 are within the ranges of 400° C.-800° C., 400° C.-500° C., and 500° C.-800° C., with regards to the above-mentioned deposition techniques, respectively. Any one or more of the following gases may be employed in forming the Si₃N₄ layer 40: SiH₄, NH₃, N₂, N₂O, SiH₂Cl₂, NH₃, N₂ and N₂O.

Next, as shown in FIG. 5, a metal layer 60 is formed over the Si₃N₄ layer 40. The metal layer 60 will serve as a hard mask during etching of the underlying Si₃N₄ layer 40, barrier oxide layer 44 and substrate 32. The metal layer 60 may include any suitable material such as for example: titanium, titanium containing alloy, tungsten, tungsten containing alloy, titanium nitride and the like. Any suitable technique for forming the metal layer 60 may be employed such as CVD, PECVD, or high density plasma chemical vapor deposition (HDPCVD) techniques.

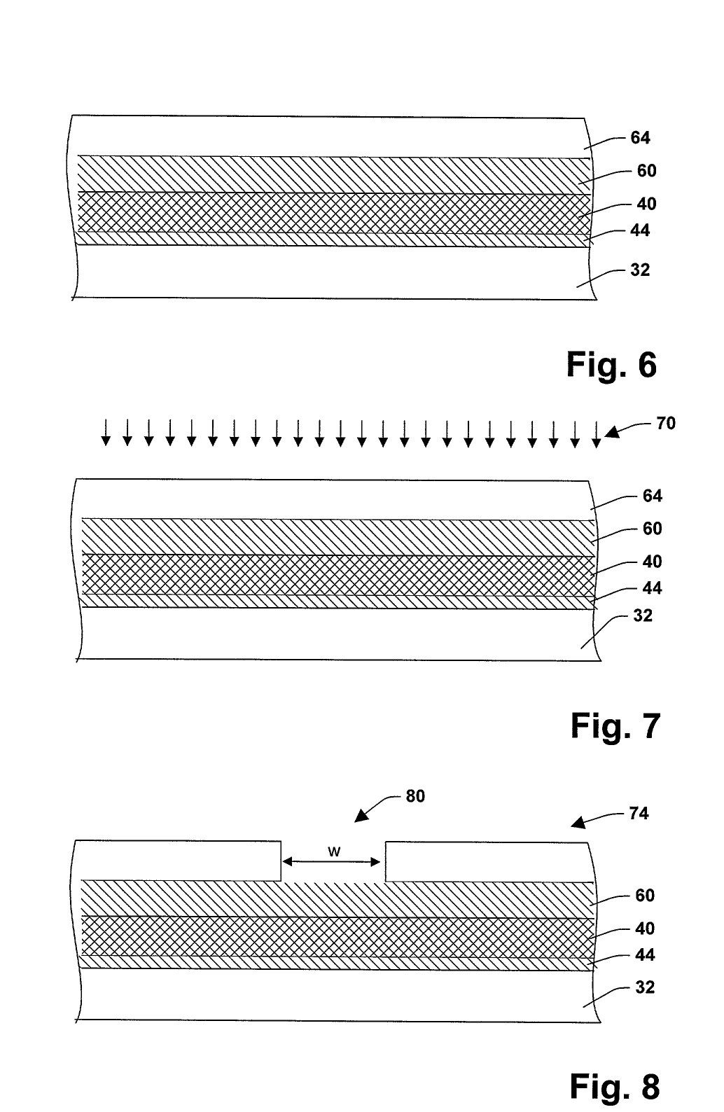

FIG. 6 illustrates an ultra-thin photoresist layer 64 formed over the metal layer 60. The ultra-thin photoresist layer has a thickness of about 500 Å-5000 Å, however, it is to be appreciated that the thickness thereof may be of any dimension suitable for carrying out the present invention. Accordingly, the thickness of the ultra-thin photoresist 64 can vary in correspondence with the wavelength of radiation used to pattern the ultra-thin photoresist 64. One aspect of the present invention provides for forming the ultra-thin photoresist layer 64 to have a thickness within the range of 1000 Å to 4000 Å. Another aspect of the present invention provides for forming the ultra-thin photoresist layer 64 to have a thickness within the range of 2000 Å to 3000 Å. Yet another aspect of the present invention provides for the ultra-thin photoresist 64 to have a thickness within the range of 500 Å to 2000 Å. The ultra-thin photoresist 64 may be formed over the metal layer 60 via conventional spin-coating or spin casting techniques deposition techniques.

The ultra-thin photoresist layer 64 has a thickness suitable for functioning as a mask for etching the underlying metal layer 60 and for forming patterns or openings in the developed ultra-thin photoresist layer 64 that are 0.25 μm or less. Since the ultra-thin photoresist layer 64 is relatively thin compared with I-line and other photoresists, improved critical dimension control is realized.

Ultra-thin resists are processed using small wavelength radiation. Small wavelength radiation increases precision and thus the ability to improve critical dimension control. Specific examples of wavelengths to which the ultra-thin photoresist 64 is sensitive (undergo chemical transformation enabling subsequent development) include about 248 nm, about 193 nm, about 157 nm, about 13 nm, about 11 nm, and as low as 4 nm. Specific sources of radiation include KrF excimer lasers having a wavelength of about 248 nm, a XeHg vapor lamp having a wavelength from about 200 nm to about 250 nm, mercury-xenon arc lamps having a wavelength of about 248 nm, an ArF excimer laser having a wavelength of about 193 nm, an F₂ excimer laser having a wavelength of about 157 nm, and X-rays having a wavelength of about 13 nm, about 11 nm, and as low as about 4 nm.

Positive or negative ultra-thin photoresists may be employed in the methods of the present invention. An example of a deep UV chemically amplified photoresist is a partially t-butoxycarbonyloxy substituted poly-p-hydroxystyrene. Photoresists are commercially available from a number of sources, including Shipley Company, Kodak, Hoechst Celanese Corporation, Brewer and IBM. The scope of the present invention as defined by the hereto appended claims is intended to include any ultra-thin photoresist suitable for carrying out the present invention.

Referring to FIG. 7, the ultra-thin photoresist layer 64 then undergoes an exposure/development step 70 to provide a patterned photoresist 74 (FIG. 8). The patterned photoresist 74 is formed using electromagnetic radiation having a relatively small wavelength (for example, less than 200 nm). In this embodiment, electromagnetic radiation having a wavelength of about 157 nm to 11 nm is employed. Since relatively small wavelengths are used, reflectivity concerns are minimized because larger wavelengths are more frequently associated with reflectivity problems. The ultra-thin photoresist layer 64 is selectively exposed to radiation; that is, selected portions of the ultra-thin photoresist layer 64 are exposed to radiation. Either the exposed or unexposed portions of the ultra-thin photoresist layer 64 are removed or developed to provide the patterned photoresist 74.

The width “w” of the cross-section of the exposed portion of the metal layer 60 (opening 80 in the patterned photoresist 74) is about 0.25 μm or less, including about 0.18 μm or less, about 0.09 μm or less, about 0.075 μm or less and about 0.05 μm or less, depending on the wavelength of radiation used.

The selectively exposed ultra-thin photoresist layer 64 is developed by contact with a suitable developer that removes either the exposed or unexposed portions of the ultra-thin photoresist layer 64. The identity of the developer depends upon the specific chemical constitution of the ultra-thin photoresist layer 64. For example, an aqueous alkaline solution may be employed to remove unexposed portions of the ultra-thin photoresist layer 64. Alternatively, one or more of dilute aqueous acid solutions, hydroxide solutions, water, and organic solvent solutions may be employed to remove selected portions of the ultra-thin photoresist layer 64. The developer is selected so that it does not degrade or etch the material of the metal layer 60, or at least degrades or etches the material of the metal layer 60 at a substantially slower rate as compared to the rate that the material of the ultra-thin photoresist layer 64 is developed. In other words, the metal layer 60 serves as an etch-stop layer when developing the ultra-thin photoresist layer 64.

The patterned photoresist 74 may assume any suitable pattern, but typically the patterned photoresist 74 corresponds to the desired STI pattern. In the present invention, the patterned photoresist 74 defines one or more shallow trenches. The patterned photoresist 74 defines one or more openings over the metal layer 60 corresponding to the shallow trench(s) to be formed. The patterned photoresist 74 serves as an etch mask layer for processing or etching the underlying metal layer 60.

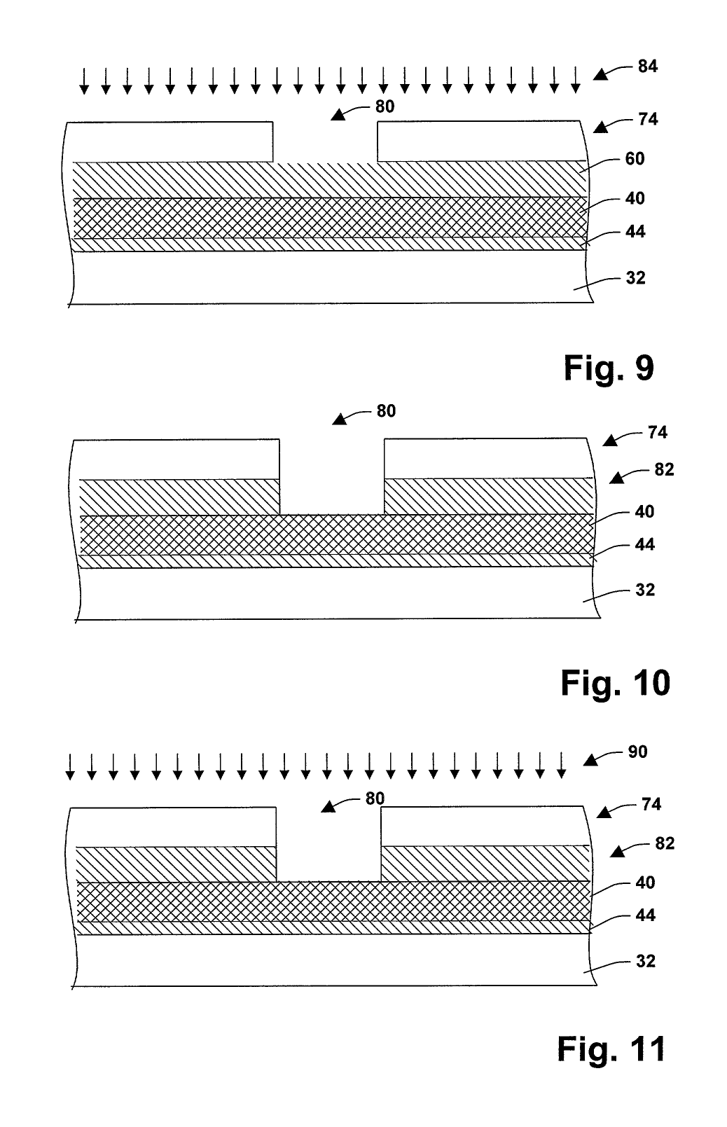

Referring to FIG. 9, the patterned photoresist 74 is used as a mask for selectively etching the metal layer 60 to provide patterned metal layer 82 from a first etch step 84. Any suitable etch technique may be used to etch the metal layer 60. Preferably, a selective etch technique may be used to etch the material of the metal layer 60 at a relatively greater rate as compared to the rates that the material of the patterned photoresist 74 is etched.

In a preferred embodiment, the metal layer 60 is etched using an anisotropic etching process—dry or wet etching techniques may be employed. A metal:photoresist etch technique may be used to etch the metal layer 60 to provide the patterned metal layer 82 and continue to define opening 80 exposing portions of the silicon nitride layer 40 lying under the patterned metal layer 80. The metal:photoresist etch selectivity may be within the range of 2:1 to 5:1, and one skilled in the art could readily tailor a suitable etch chemistry to correspond to the characteristics of the metal layer 60 and the patterned photoresist 74. For example, using the patterned photoresist 74 as a mask, the metal layer 60 (e.g., in this particular example comprising tunsten (W)) is selectively etched with an etchant consisting of either fluorine based or chlorine based chemistries, which are highly selective of the tungsten over the photoresist 74, to form a patterned metal layer 84 exposing a portion of the silicon nitride layer 40. In one specific aspect of the present invention, the first etch step 84 includes a high selectivity fluorocarbon plasma etch (e.g., CHF₃, C₂F₆).

Turning now to FIG. 11, the Si₃N₄ layer 40, barrier oxide layer 44 and the substrate 32 are shown undergoing an etching process 90 wherein the patterned metal layer 84 serves a mask thereto. For example, the etching process 90 may include a reactive ion etch (RIE), that is highly selective of the Si₃N₄ layer with respect to the metal layer 84. Alternatively, for example, the second etch chemistry may include HBr/HeO₂ based chemistries which are highly selective to the Si₃N₄ over the metal layer 84. In another specific embodiment, the second etch chemistry may be fluorine based including (CF₄/O₂, or CHF₃, or a combination thereof). It is to be appreciated that any suitable etch methodology for selectively etching the Si₃N₄ layer 44 over the patterned metal layer 84 may be employed and is intended to fall within the scope of the hereto appended claims. The ultra-thin photoresist 74 will be removed as well during the etch process 90 partly because of its thinness and inability to serve as a sole etch barrier for the Si₃N₄ layer etch. However, if desired the ultra-thin photoresist 74 may be stripped away prior to performing the etch process 90.

Furthermore, the barrier oxide layer 40 and the substrate 32 are also etched during the etch process 90. It is understood that the etch process 90 may include one or more etch methodologies for removing the various layers. It is to be appreciated that the chemistry of the etch process 90 should provide for etching of the barrier oxide layer 40 and the substrate 32, and furthermore the ratio of thickness of the metal layer 60 to the barrier oxide layer 40 should be selected so as to facilitate a desired etching result. More particularly, the ratio of thickness of the metal layer 60 to the barrier oxide layer 40 preferably is greater than 2:1 so that the metal layer 60 will serve as an adequate hard mask while the exposed portion of the barrier oxide layer 40 and underlying portion of the substrate 32 are suitably etched during the etch process 90.

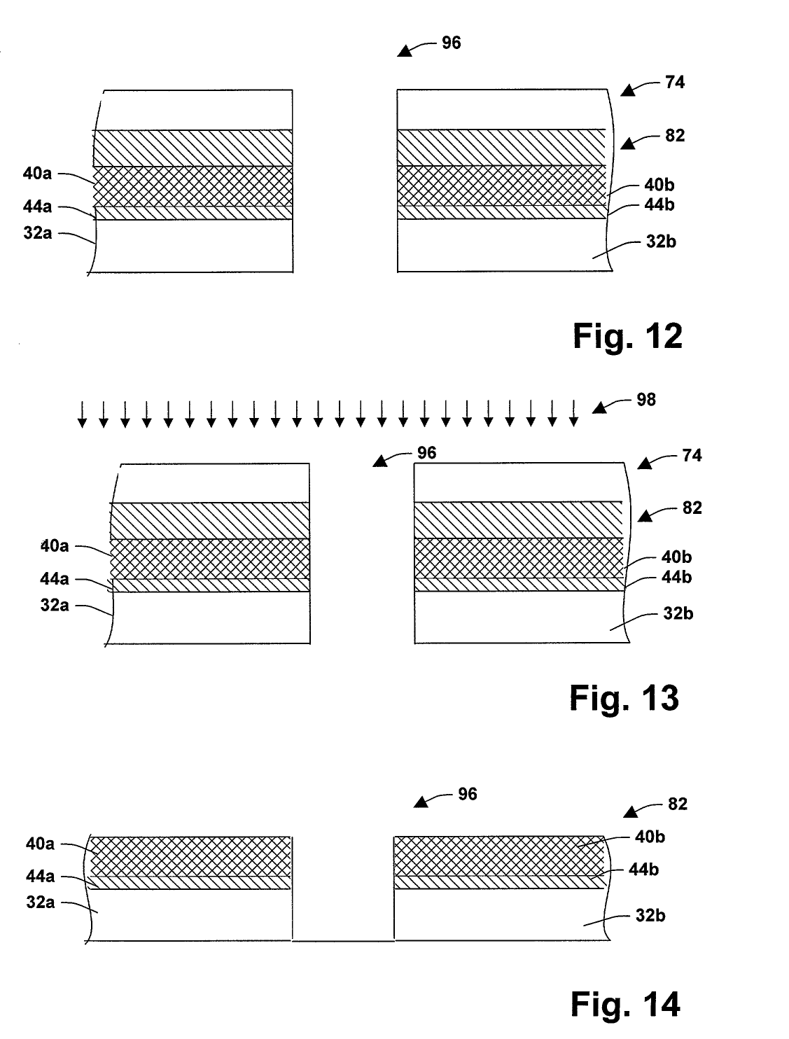

FIG. 12 illustrates a shallow trench 96 formed in substantial part. Next, in FIG. 13, a photoresist strip/silicon nitride layer removal process 98 is performed to remove the patterned photoresist layer 82 and the patterned metal layer 40. Any suitable technique for stripping the photoresist layer 82 may be employed. Likewise, any suitable technique (e.g., using an oxidizing cleaning solution such as an ammonium hydroxide and hydrogen peroxide based solution (APM), or a sulfuric acid and hydrogen peroxide based solution (SPM)) may be employed to remove the metal hard mask 82. FIG. 14 illustrates the shallow trench structure after the process 98 is substantially complete.

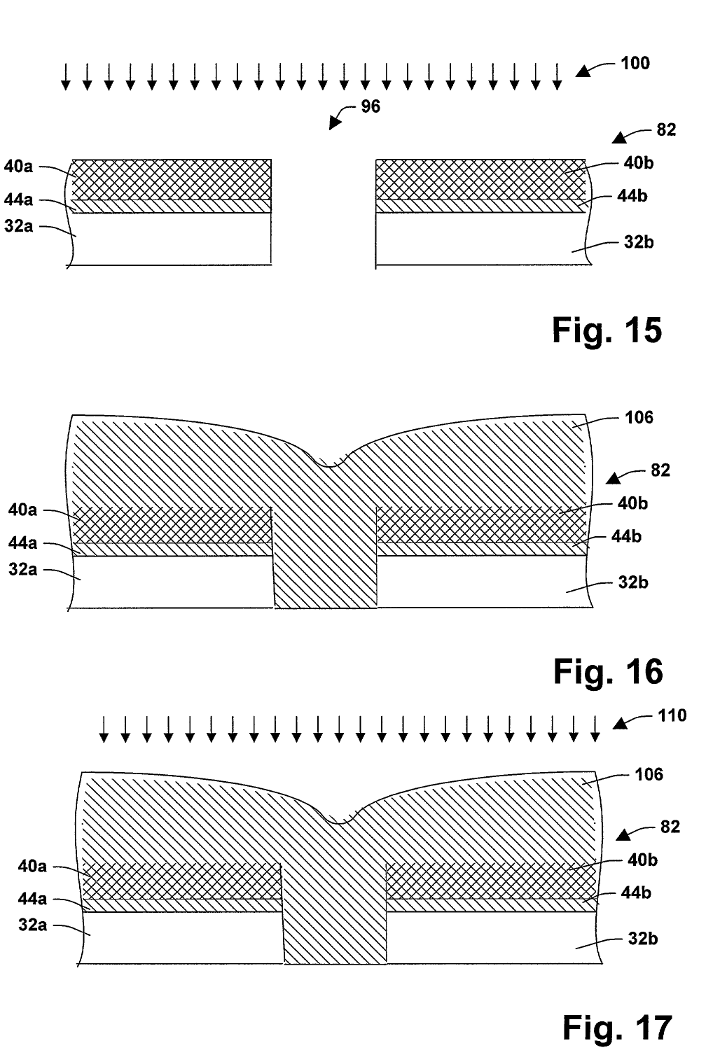

Thereafter, in FIG. 15 the shallow trench structure 96 undergoes a trench filling process 100 wherein an insulating filler material 106 (e.g., SiO₂) is deposited over the structure so as to fill the shallow trench 96 with the insulating material as shown in FIG. 16. The filled shallow trench 96 will serve as an insulating boundary between devices within the substrate regions 32a, 32b, respectively. Although SiO₂ is preferred as the insulating material 106, any suitable material (e.g., SiO, TEOS, polyimides; Teflon, aerogels and silicon oxynitride) may be employed.

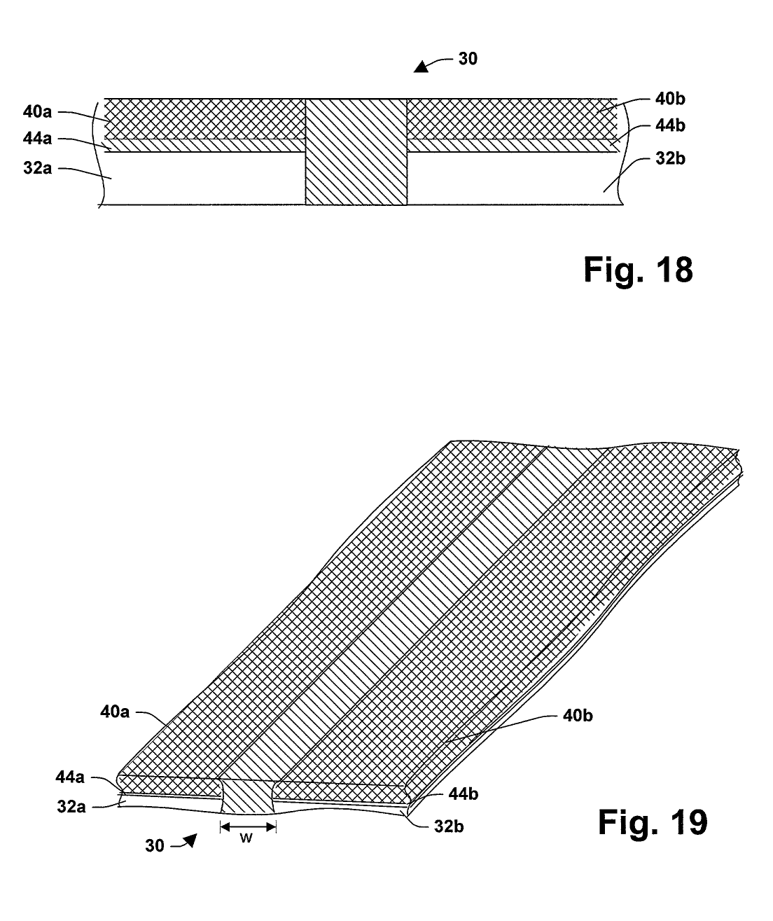

In FIG. 17, a chemical mechanical polishing step 110 is performed to remove and planarize the filler 106 so as to result in the shallow trench structure 30 shown in FIGS. 18-19. Thereafter, standard STI process steps are performed to finalize the ultimately desired shallow trench isolation.

Thus the present invention provides for a method of fabricating a shallow trench isolation structure with dimensions below about the 0.25 μm level.

What has been described above are preferred embodiments of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims.

What is claimed is:

1. A method of forming a shallow trench isolation, comprising the steps of:
forming a barrier oxide layer on a substrate;
forming a silicon nitride layer on the barrier oxide layer;
forming a metal layer on the silicon nitride layer;
forming an ultra-thin photoresist layer on the metal layer;
patterning the ultra-thin photoresist layer with short wavelength radiation to define a pattern for a shallow trench;
using the ultra-thin photoresist layer as a mask during a first etch step to transfer the shallow trench pattern to the metal layer, the first etch step including an etch chemistry that is selective to the metal layer over the ultra-thin photoresist layer; and
using the metal layer as a hard mask during a second etch step to form the shallow trench by etching portions of the silicon nitride layer, barrier oxide layer and substrate.

2. The method of claim 1 further including the step of filling the shallow trench with an insulating dielectric material.

3. The method of claim 2 further including the step of using at least one of SiO, SiO₂, TEOS, polyimides; Teflon, aerogels and silicon oxynitride as the insulating dielectric material.

4. The method of claim 1, further including the step of forming the barrier oxide layer to have a thickness within the range of about 50 Å to 150 Å.

5. The method of claim 1, further including the step of forming the nitride layer to have a thickness within the range of about 1000 Å to 2000 Å.

6. The method of claim 1, further including the step of forming the metal layer to have a thickness within the range of about 100 Å to 1000 Å.

7. The method of claim 1, further including the step of forming the ultra-thin photoresist layer to have a thickness within the range of about 500 Å to 5000 Å.

8. The method of claim 1, further including the step of forming the ultra-thin photoresist layer to have a thickness within the range of about 1000 Å to 4000 Å.

9. The method of claim 1, further including the step of forming the ultra-thin photoresist layer to have a thickness within the range of about 2000 Å to 3000 Å.

10. The method of claim 1, further including the step of forming the ultra-thin photoresist layer to have a thickness within the range of about 500 Å to 2000 Å.

11. The method of claim 1, further including the step of using radiation having a wavelength less than about 200 nm.

12. The method of claim 1, further including the step of using radiation having a wavelength less than about 160 nm.

13. The method of claim 1, further including the step of using radiation having a wavelength less than about 100 nm.

14. The method of claim 1, further including the step of using radiation having a wavelength less than about 13 nm.

15. The method of claim 1, further including the step of using radiation having a wavelength less than about 11 nm.

16. The method of claim 1, further including the step of using radiation having a wavelength of about 13 nm.

17. The method of claim 1, further including the step of using X-rays as the radiation.

18. The method of claim 1, further including the step of using extreme ultra-violet radiation as the short wavelength radiation.

19. The method of claim 1, further including the step of using deep ultraviolet radiation as the short wavelength radiation.

20. The method of claim 1, further including an etch chemistry for the first etch having a selectivity to the metal layer over the ultra-thin photoresist layer greater than about 2:1.

21. The method of claim 1, further including an etch chemistry for the first etch having a selectivity to the metal layer over the ultra-thin photoresist layer greater than about 3:1.

22. The method of claim 1, further including an etch chemistry for the first etch having a selectivity to the metal layer over the ultra-thin photoresist layer greater than about 4:1.

23. The method of claim 1, further including an etch chemistry for the second etch having a selectivity to the silicon nitride layer over the metal layer greater than about 2:1.

24. The method of claim 1, further including an etch chemistry for the second etch having a selectivity to the silicon nitride layer over the metal layer greater than about 3:1.

25. The method of claim 1, further including an etch chemistry for the second etch having a selectivity to the silicon nitride layer over the metal layer greater than about 4:1.

26. The method of claim 1, further including the step of using a fluorine based chemistry in the first etch step.

27. The method of claim 1, further including the step of using a high selectivity fluorocarbon plasma in the first etch step.

28. The method of claim 1, further including the step of using a chlorine based etch chemistry in the first etch step.

29. The method of claim 1, further including the step of using a reactive ion etch in the second etch step.

30. The method of claim 1, further including the step of using an HBr/HeO₂ based etch chemistry in the second etch step.

31. The method of claim 1, further including the step of using an etch chemistry comprising at least one of: CF₄/O₂; CHF₃; and combination thereof in the second etch step.

32. The method of claim 1, further including the step of using titanium as at least part of the metal layer.

33. The method of claim 1, further including the step of using tungsten as at least part of the metal layer.

34. The method of claim 1, further including the step of using titanium nitride as at least part of the metal layer.

35. A shallow trench isolation structure having a width below about 0.18 μm, formed by a method including the steps of:
forming a barrier oxide layer on a substrate;
forming a silicon nitride layer on the barrier oxide layer;
forming a metal layer on the silicon nitride layer;
forming an ultra-thin photoresist layer on the metal layer;
patterning the ultra-thin photoresist layer with extreme ultra-violet radiation to define a pattern for a shallow trench;
using the ultra-thin photoresist layer as a mask during a first etch step to transfer the shallow trench pattern to the metal layer, the first etch step including an etch chemistry that is selective to the metal layer over the ultra-thin photoresist layer; and
using the metal layer as a hard mask during a second etch step to form the shallow trench by etching portions of the silicon nitride layer, barrier oxide layer and substrate.

36. A method of forming a shallow trench isolation, comprising the steps of:
forming a barrier oxide layer on a substrate, the barrier oxide having a thickness within the range of about 50 Å to 150 Å;
forming a silicon nitride layer on the barrier oxide layer, the silicon nitride layer having a thickness within the range of about 1000 Å to 2000 Å;
forming a metal layer on the silicon nitride layer, the metal layer having a thickness within the range of about 100 Å to 1000 Å;
forming an ultra-thin photoresist on the metal layer, the ultra-thin photoresist having a thickness within the range of about 500 Å to 500 Å;
patterning the ultra-thin photoresist layer with short wavelength radiation to define a pattern for a shallow trench;
using the ultra-thin photoresist layer as a mask during a first etch step to transfer the shallow trench pattern to the metal layer, the first etch step including an etch chemistry that is selective to the metal layer over the ultra-thin photoresist layer; and
using the metal layer as a hard mask during a second etch step to form the shallow trench by etching portions of the silicon nitride layer, barrier oxide layer and substrate.
